(19) United States
(12) Patent Application Publication
(10) Pub. No.: US 2026/0274183 A1
(43) Pub. Date: Sep. 17, 2026

(54) BRIDGE CIRCUIT FOR BATTERY MANAGEMENT SYSTEM

(71) Applicant: Analog Devices International Unlimited Company, Limerick (IE)

(72) Inventors: Junliang Chen, Beijing (CN); Rengui Luo, Beijing (CN); Huimei Wang, Beijing (CN); Yong Wang, Beijing (CN); Pengcheng Li, Beijing (CN)

(21) Appl. No.: 19/554,415

(22) Filed: Mar. 2, 2026

Related U.S. Application Data
(60) Provisional application No. 63/770,872, filed on Mar. 12, 2025.

(51) Int. Cl. B60R 16/023; G01R 31/382; G01R 31/396

(52) U.S. Cl. CPC B60R 16/023; G01R 31/382; G01R 31/396

(57) ABSTRACT

A bridge circuit for use in an automotive battery management system can include a first communication interface that can be configured to communicate with a control unit using a first bus protocol. The bridge circuit can also include a second communication interface that can be configured to communicate with one or more peripheral battery management devices using a second bus protocol. The bridge circuit can also include a memory storing a plurality of sequences. An individual sequence of the plurality of sequences can include one or more commands for the one or more peripheral battery management devices. The bridge circuit can also include a sequence controller that can be coupled to the memory and can be configured to retrieve one or more commands associated with a selected sequence from the memory, transmit the retrieved one or more commands to the one or more peripheral battery management devices using the second communication interface, and store data received from the one or more peripheral battery management devices in response to a read command in the memory.

### CLAIM OF PRIORITY

This patent application claims the benefit of priority of Chen et al., U.S. Provisional Patent Application Ser. 63/770,872, entitled “EFFECTIVE SEQUENCER ARCHITECTURE FOR INTERFACE BUS BRIDGE,” filed on Mar. 12, 2025 (Attorney Docket No. 3867.D68PRV), which is hereby incorporated by reference herein in its entirety.

### TECHNICAL FIELD

The present disclosure relates to automotive battery management systems, and more particularly, but not by way of limitation, to a sequencer architecture for a bus protocol bridge circuit that manages communication between a control unit and one or more peripheral battery management devices.

### BACKGROUND

Electric and hybrid electric vehicles can use battery packs including multiple cells connected in series and/or parallel configurations to provide a desired voltage and capacity. Monitoring the voltage, current, and temperature of individual cells or groups of cells within the battery pack can be used to support functions such as state-of-charge estimation, cell balancing, and fault detection.

Automotive battery management systems can include one or more peripheral devices, such as analog front-end circuits, that monitor parameters of individual cells or groups of cells in a battery pack. A control unit, such as a microcontroller or a domain controller, can communicate with these peripheral devices over one or more communication buses to retrieve measurement data and send configuration commands.

### SUMMARY

In an example, a bridge circuit for use in an automotive battery management system can include a first communication interface that can be configured to communicate with a control unit using a first bus protocol. The bridge circuit can also include a second communication interface that can be configured to communicate with one or more peripheral battery management devices using a second bus protocol. The bridge circuit can also include a memory storing a plurality of sequences. An individual sequence of the plurality of sequences can include one or more commands for the one or more peripheral battery management devices. The bridge circuit can also include a sequence controller that can be coupled to the memory and can be configured to retrieve one or more commands associated with a selected sequence from the memory, transmit the retrieved one or more commands to the one or more peripheral battery management devices using the second communication interface, and store data received from the one or more peripheral battery management devices in response to a read command in the memory.

In an example, a method for operating a bridge circuit for use in an automotive battery management system can be provided. The bridge circuit can include a first communication interface that can be configured to communicate with a control unit using a first bus protocol, a second communication interface that can be configured to communicate with one or more peripheral battery management devices using a second bus protocol, a memory storing a plurality of sequences, an individual sequence of the plurality of sequences can include one or more commands for the one or more peripheral battery management devices, and a sequence controller that can be coupled to the memory. The method can include retrieving, using the sequence controller, one or more commands associated with a selected sequence from the memory. The method can also include transmitting, using the second communication interface, the retrieved one or more commands to the one or more peripheral battery management devices. The method can also include storing, using the sequence controller, data received from the one or more peripheral battery management devices in response to a read command in the memory.

In an example, a bridge circuit for use in an automotive battery management system can include a first communication interface that can be configured to communicate with a control unit using a first bus protocol. The bridge circuit can also include a second communication interface that can be configured to communicate with one or more peripheral battery management devices using a second bus protocol. The bridge circuit can also include a memory storing a plurality of sequences. An individual sequence of the plurality of sequences can include one or more commands for the one or more peripheral battery management devices. The bridge circuit can also include a sequence controller that can be coupled to the memory and can be configured to divide time into discrete time slots with a specified slot length, maintain a sequence ready list indicating which of the sequences can be ready for execution in a current time slot, select a ready sequence having a highest priority from the sequence ready list, retrieve one or more commands associated with the selected sequence from the memory, and transmit the retrieved one or more commands to the one or more peripheral battery management devices using the second communication interface.

### BRIEF DESCRIPTION OF THE DRAWINGS

In the drawings, which may not be drawn to scale, like numerals may describe substantially similar components throughout one or more of the views. Like numerals having different letter suffixes may represent different instances of substantially similar components. The drawings illustrate generally, by way of example but not by way of limitation.

FIG. 1 shows a block diagram of an example of portions of a battery management system.

FIG. 2 shows a block diagram of an example of a sequence and command structure.

FIG. 3 shows a block diagram of an example of determining a sequence ready list.

FIG. 4 shows a timing diagram of an example of a sequence execution order.

FIG. 5 shows a timing diagram of an example of an emergency sequence injection process.

FIG. 6 shows a block diagram showing an example of the operation of portions of a sequence controller.

FIG. 7 shows a block diagram of an example of a buffer structure within a battery management system

FIG. 8 shows an example of portions of a method for operating a bridge circuit.

FIG. 9 is a block diagram of an example of portions of a machine upon which one or more portions of the present disclosure may be implemented.

### DETAILED DESCRIPTION

In an approach used in some battery management system architectures, a dedicated microcontroller local to the battery pack can manage communication with peripheral battery management devices, such as analog front-end circuits, and can execute measurement sequences, perform calculations, and handle fault detection using locally stored firmware. In such architectures, the microcontroller and its firmware can be tightly coupled to the specific hardware of the peripheral devices, such that changes to the peripheral devices or updates to the measurement sequences can require corresponding firmware modifications. Additionally, the microcontroller can consume bus bandwidth on a communication link shared with a higher-level control unit, such as a domain controller, because each individual command to and response from the peripheral devices can be relayed across that shared link.

The present inventor has recognized, among other things, that a bridge circuit can be interposed between a control unit and one or more peripheral battery management devices, such as to handle one or more of traffic between the peripheral devices and the control unit, sequencing and sending commands to the peripheral devices (e.g., commands to configure the peripheral battery management devices, commands to read from the peripheral battery management devices), or receiving and/or buffering data from the peripheral battery management devices. The bridge circuit can include a sequence controller and a local memory storing a plurality of pre-configured sequences of commands. During a configuration phase, the control unit can load the sequences into the memory over a first communication interface. During runtime, the sequence controller can retrieve and execute the stored commands autonomously over a second communication interface to the peripheral devices, without requiring per-command intervention from the control unit. Data received from the peripheral devices in response to read commands can be stored in the local memory, and the control unit can read the stored data asynchronously over the first communication interface. This arrangement can help reduce bus traffic on the link between the control unit and the bridge circuit, and can help allow the measurement sequences to be updated by rewriting the memory contents without requiring firmware changes to the bridge circuit or the control unit.

The bridge circuit may not include a full microcontroller circuit (e.g., a circuit capable of executing a full instruction set, such as an ARM (advanced RISC (reduced instruction set controller) machine) controller). Instead, the bridge circuit can include hardware (e.g., digital and/or analog hardware) capable of performing the functions of the bridge circuit, such as without additional hardware.

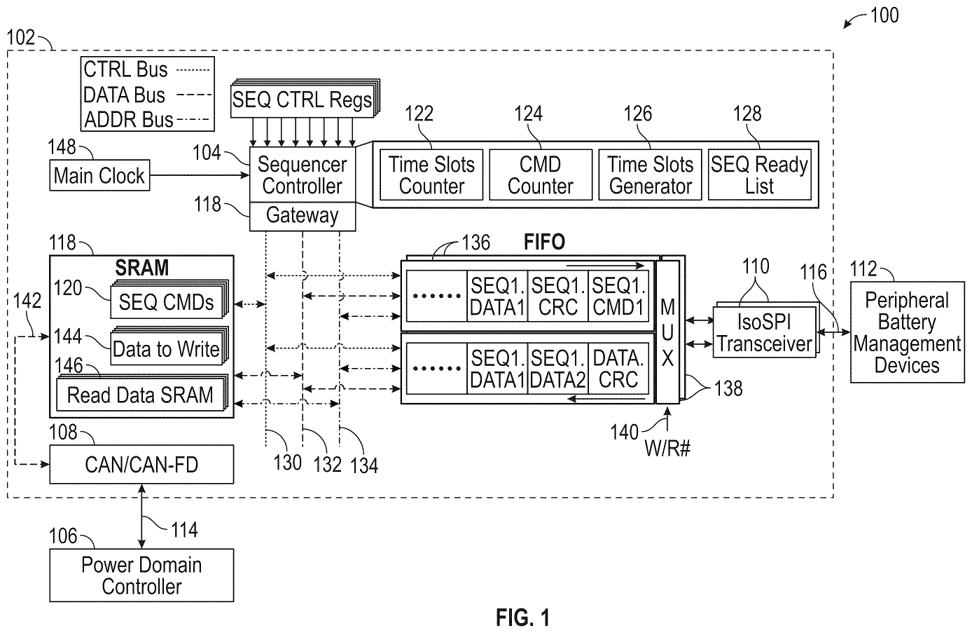

FIG. 1 shows a block diagram of an example of portions of a battery management system 100. FIG. 1 shows an example of portions of a bridge circuit 102 including portions of an environment in which the bridge circuit 102 can be used. FIG. 1 shows that the battery management system 100 can include a bridge circuit 102, a control unit 106, and one or more Peripheral battery management devices 112. The bridge circuit 102 can be interposed between the control unit 106 and the one or more Peripheral battery management devices 112, such as to manage communication between them.

The bridge circuit 102 can include a first communication interface 108, a second communication interface 110, a memory 118, and a sequence controller 104. The bridge circuit 102 can also include a first-in-first-out (FIFO) buffer 136 and a multiplexer 138.

The first communication interface 108 can be configured to communicate with the control unit 106, such as using a first bus protocol. In an example, the first bus protocol can be a Controller Area Network (CAN) protocol or a CAN with Flexible Data-Rate (CAN-FD) protocol. In other examples, the first bus protocol can be any other bus protocol, such as can include a Serial Peripheral Interface (SPI) protocol, an Inter-Integrated Circuit (I2C) protocol, a Universal Asynchronous Receiver-Transmitter (UART) protocol, an Ethernet protocol, or any other wired or wireless communication protocol. The first communication interface 108 can be coupled to the control unit 106 via a first bus 114. The control unit 106 can be a power domain controller, a zone controller, a domain controller, a microcontroller, or any other processing unit capable of communicating over the first bus 114. The control unit 106 can be capable of executing instructions, such as a full instruction set (e.g., an ARM processor). The control unit 106 can be configured to handle one or more operations in an automotive system, such as including one or more battery management functions. In an example, the control unit 106 can perform other automotive functions (e.g., collision detection and avoidance, parking assistance, blind spot monitoring, etc.). In an example, there can be two or more control units 106, coupled to the first bus 114. For example, one or more of the two or more control units 106 can write data to the memory 118 (e.g., to program sequences), read data from the memory 118 (e.g., to receive measurement information), or both.

The second communication interface 110 can be configured to communicate with the one or more peripheral battery management devices 112 using a second bus protocol. In an example, the second communication interface 110 can be an isolated Serial Peripheral Interface (isoSPI) transceiver. In other examples, the second bus protocol can be any other bus protocol, such as can include SPI, I2C, a daisy-chain protocol, or any other wired or wireless communication protocol. The second communication interface 110 can be coupled to the one or more peripheral battery management devices 112 via a second bus 116. In an example, the second bus protocol can be different from the first bus protocol. In an example, the second bus protocol can be the same as the first bus protocol.

The one or more peripheral battery management devices 112 can include one or more analog front-end circuits, one or more power management circuits, or any other devices configured to interact with cells or groups of cells in a battery pack. In an example, at least one of the one or more peripheral battery management devices 112 can include an analog front-end circuit configured to measure at least one of a cell voltage, a cell current, or a cell temperature of at least one cell or group of cells in a battery pack. In an example, the one or more peripheral battery management devices 112 can include one or more analog front-end circuits configured to perform one or more diagnostic functions and/or functional safety checks, such as can include one or more of open wire detection, redundancy checking, short circuit detection, over current detection, overtemperature detection, under temperature detection, or overvoltage or undervoltage detection. The one or more peripheral battery management devices 112 can be connected in a daisy-chain configuration along the second bus 116, such that a command transmitted by the second communication interface 110 can propagate through each of the peripheral battery management devices 112 in sequence. In other examples, the one or more peripheral battery management devices 112 can be connected in a star configuration, a ring configuration, or any other topology.

In an example, the one or more peripheral battery management devices 112 can be connected in a ring configuration, such that the second communication interface 110 includes two transceiver ports. A first transceiver port can be coupled to a first end of the daisy chain of peripheral battery management devices 112, and a second transceiver port can be coupled to a second end of the daisy chain. In such a configuration, if a connection between two of the peripheral battery management devices 112 is broken, the sequence controller 104 can use the first transceiver port to communicate with a first subset of the peripheral battery management devices 112 and the second transceiver port to communicate with a second subset of the peripheral battery management devices 112, such as to provide redundancy.

The memory 118 can be a static random-access memory (SRAM) or any other type of volatile or non-volatile memory. The memory 118 can store one or more (e.g., a plurality of) sequences. An individual sequence of the plurality of sequences include one or more commands for the one or more peripheral battery management devices 112. The memory 118 can include a sequence command area 120, a write data area 144, and a read data area 146. The sequence command area 120 can store command headers and command data for the plurality of sequences. The write data area 144 can store data payloads to be written to the one or more peripheral battery management devices 112, such as in response to write commands. The read data area 146 can store data received from the one or more peripheral battery management devices 112 in response to read commands. In an example, the memory 118 can also store configuration data, such as can include sequence control registers, command handlers, type definitions, and other parameters used by the sequence controller 104.

The memory 118 can be coupled to the first communication interface 108 via a communication bus 142. The control unit 106 can read data from the memory 118 and write data to the memory 118 using the first communication interface 108 via the communication bus 142. In an example, the control unit 106 can read stored data from the memory 118 asynchronously with respect to the storage of received data from the one or more peripheral battery management devices 112. For example, the sequence controller 104 can store data received from the peripheral battery management devices 112 in the read data area 146 of the memory 118 at times determined by the sequence controller 104, and the control unit 106 can read the stored data from the memory 118 at times determined by the control unit 106, such as without requiring synchronization between the two operations.

In an example, the plurality of sequences can be loaded into the memory 118 by the control unit 106 using the first communication interface 108, such as during a configuration phase. The configuration phase can occur after power-up of the bridge circuit 102 and before the sequence controller 104 begins autonomous execution of the sequences. During the configuration phase, the control unit 106 can write the command headers, command data, write data payloads, type definitions, and configuration parameters to the memory 118, such as in a prescribed format. After the configuration phase, during runtime, the sequence controller 104 can execute the sequences without further intervention from the control unit 106. In an example, during runtime following the configuration phase, the control unit 106 can initiate a reconfiguration phase, including loading one or more new or modified sequences into the memory 118 using the first communication interface 108, such as to update measurement sequences or safety routines, such as without requiring a reboot or firmware change to the bridge circuit 102 or the control unit 106.

The sequence controller 104 can be coupled to the memory 118 and can be configured to one or more of (1) retrieve one or more commands associated with a selected sequence from the memory 118, (2) transmit the retrieved one or more commands to the one or more peripheral battery management devices 112 using the second communication interface 110, or (3) store data received from the one or more peripheral battery management devices 112 in response to a read command in the memory 118. The sequence controller 104 can receive a main clock signal (e.g., from the main clock 148) and can use the main clock signal to time its operations. The bridge circuit 102 might not include a full microcontroller circuit (e.g., a circuit capable of executing a full instruction set, such as an ARM controller). Instead, the bridge circuit 102 can include hardware, such as digital logic and/or analog circuitry, configured to perform the functions of the sequence controller 104 and other components of the bridge circuit 102. In an example, the bridge circuit 102 can include a microcontroller circuit (e.g., a full microcontroller circuit). The microcontroller circuit can be programmed using specified firmware, such that it carries out the specified operations of the bridge circuit 102.

The sequence controller 104 can include or be coupled to a time slots counter 122, a command counter 124, a time slots generator 126, and a sequence ready list 128. The sequence controller 104 can also include or be coupled to one or more sequence control registers, such as can store parameters for each of the plurality of sequences.

The time slots generator 126 can be configured to divide time into discrete time slots, such as with a specified slot length. The time slot length can be configurable by the control unit 106 during the configuration phase. In an example, the time slot length can be on the order of microseconds, such as can include 1 microsecond, 10 microseconds, 50 microseconds, 100 microseconds, or any other duration. The time slots counter 122 can track the current time slot number. The command counter 124 can track which command within a currently executing sequence is being processed.

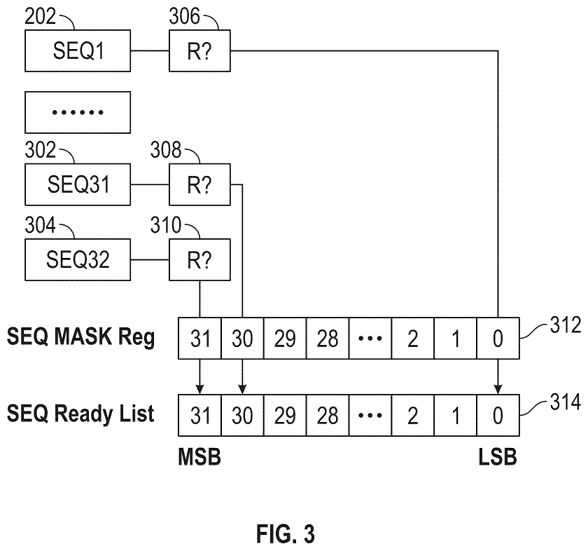

The sequence ready list 128 can indicate which of the plurality of sequences are ready for execution in a current time slot. The sequence ready list 128 is discussed in more detail below with respect to FIG. 3. The sequence controller 104 can be configured to maintain the sequence ready list 128 and, at the beginning of each time slot or at other times, check the sequence ready list 128 to determine which sequences are ready for execution. In an example, each sequence of the plurality of sequences can have an associated priority, and the sequence controller 104 can be configured to select a ready sequence having a highest priority from the sequence ready list 128 for execution. The sequence controller 104 can retrieve the one or more commands associated with the selected sequence from the memory 118 and transmit the retrieved one or more commands to the one or more peripheral battery management devices 112 using the second communication interface 110.

The sequence controller 104 can be configured to enter a low-power mode when no remaining sequences are ready for execution in a current time slot. In the low-power mode, the sequence controller 104 can reduce or cease activity until the next time slot begins, such as to conserve power.

The sequence controller 104 can communicate with the memory 118 and other components of the bridge circuit 102 via an internal bus structure that can include a control bus 130, a data bus 132, and an address bus 134. The sequence controller 104 can include a gateway interface that can manage data flow between the memory 118, the FIFO buffer 136, and the internal bus structure.

The FIFO buffer 136 can be arranged between the sequence controller 104 and the second communication interface 110. The FIFO buffer 136 can temporarily store command data and response data during communication with the one or more peripheral battery management devices 112. In an example, the FIFO buffer 136 can store command codes, error-checking data (such as a cyclic redundancy check (CRC) value), and command data for a command being transmitted to the peripheral battery management devices 112. In another example, the FIFO buffer 136 can store response data received from the peripheral battery management devices 112 before the response data is written to the read data area 146 of the memory 118.

The multiplexer 138 can be arranged between the FIFO buffer 136 and the second communication interface 110. A read/write selection node 140 can control the multiplexer 138 to select between a write direction (transmitting data from the FIFO buffer 136 to the second communication interface 110) and a read direction (receiving data from the second communication interface 110 into the FIFO buffer 136). In an example, for a write command, the sequence controller 104 can set the read/write selection node 140 to the write direction, such that command codes, CRC data, and write data payloads from the FIFO buffer 136 are transmitted through the multiplexer 138 to the second communication interface 110 and then to the one or more peripheral battery management devices 112 over the second bus 116. For a read command, after the command code and CRC data have been transmitted, the sequence controller 104 can set the read/write selection node 140 to the read direction, such that response data from the one or more peripheral battery management devices 112 is received through the second communication interface 110, passed through the multiplexer 138, and stored in the FIFO buffer 136. The sequence controller 104 can then transfer the received data from the FIFO buffer 136 to the read data area 146 of the memory 118.

In operation, during the configuration phase, the control unit 106 can load the plurality of sequences and associated configuration data into the memory 118 via the first communication interface 108 and the communication bus 142. After the configuration phase, the control unit 106 can instruct the sequence controller 104 to begin execution. The sequence controller 104 can then operate autonomously, dividing time into discrete time slots using the time slots generator 126, checking the sequence ready list 128 at the beginning of each time slot, selecting the ready sequence with the highest priority, retrieving the commands for the selected sequence from the sequence command area 120 of the memory 118, and transmitting the commands to the one or more peripheral battery management devices 112 via the FIFO buffer 136, the multiplexer 138, and the second communication interface 110. Data received from the one or more peripheral battery management devices 112 in response to read commands can be stored in the read data area 146 of the memory 118. The control unit 106 can read the stored data from the memory 118 using the first communication interface 108 at any time, asynchronously with respect to the operations of the sequence controller 104.

During runtime, the control unit 106 can also load an emergency sequence into the memory 118 using the first communication interface 108 (e.g., as discussed below in more detail with respect to FIG. 5). The emergency sequence can be loaded while the sequence controller 104 is executing other sequences. The sequence controller 104 can be configured to execute the emergency sequence the next time the sequence ready list 128 is checked, such as at the completion of a currently executing sequence or at the beginning of the next time slot. In an example, the emergency sequence can have a highest priority among the sequences in the sequence ready list 128, such that the emergency sequence is selected for execution before any other ready sequence. The emergency sequence can be used to initiate a protective action, such as disconnecting a battery pack, in response to a fault condition detected by the control unit 106.

In an example, the control unit 106 might not be linked to the bridge circuit 102 and/or the peripheral battery management devices 112 other than through the first communication interface 108. For example, the control unit 106 might only be able to access the memory 118 directly, such as can include not being able to directly access the peripheral battery management devices 112 or the sequence controller 104.

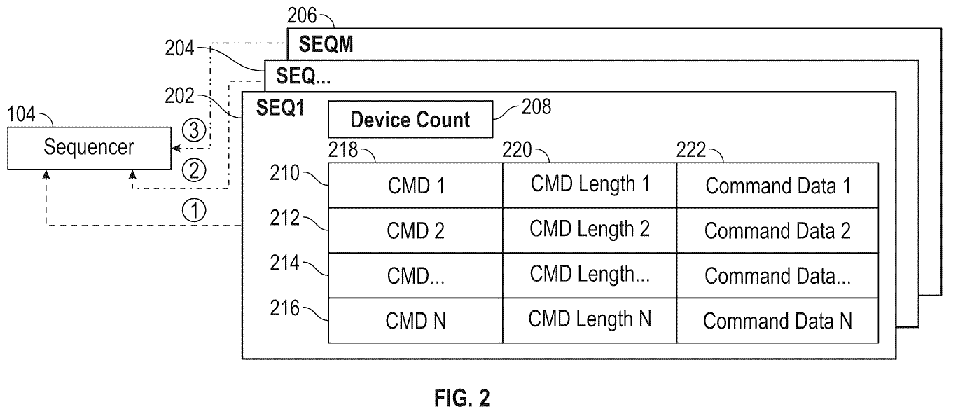

FIG. 2 shows a block diagram of an example of a sequence and command structure, such as can be stored in the memory 118. FIG. 2 shows that the sequence controller 104 can manage a plurality of sequences. The plurality of sequences can include a first sequence (SEQ1) 202, one or more intermediate sequences (SEQ . . . ) 204, and an Mth sequence (SEQM) 206. The number of sequences M can be any positive integer. In an example, M can be up to 32, such as can include 32 sequences per isoSPI port when the second communication interface 110 includes two transceiver ports (e.g., the selected transceiver port or ports can be specified by the sequence controller 104 or the sequence commands). In other examples, M can be any other value, such as 8, 16, 64, or any other number.

The sequence controller 104 can output one or more control signals to manage the retrieval and execution of commands from the sequences. FIG. 2 shows three control signals, labeled 1, 2, and 3, extending from the sequence controller 104 to the first sequence (SEQ1) 202. These control signals can be used to select a sequence from among the plurality of sequences, to advance through the commands within the selected sequence, and to coordinate the transfer of command data between the memory 118, the FIFO buffer 136, and the second communication interface 110. In other examples, the sequence controller 104 can use fewer or more control signals.

Each sequence of the plurality of sequences can include a device count 208 and one or more commands. The device count 208 can indicate a number of peripheral battery management devices 112 from which data is to be read or to which data is to be written for the commands in that sequence. In an example, the device count 208 can range from 1 to 32. In other examples, the device count 208 can be any other value. When the peripheral battery management devices 112 are connected in a daisy-chain configuration, a single command transmitted by the second communication interface 110 can propagate through all of the peripheral battery management devices 112 indicated by the device count 208, and each device can return its response data in sequence. The amount of data received for a given read command can be equal to the command length multiplied by the device count 208.

FIG. 2 shows that the first sequence (SEQ1) 202 can include a command 1 (CMD 1) 210, a command 2 (CMD 2) 212, one or more intermediate commands (CMD . . . ) 214, and a command N (CMD N) 216. The number of commands N in a given sequence can be any positive integer. In an example, N can be up to 127. In other examples, N can be any other value. The commands within a sequence can be executed in order by the sequence controller 104, such that command 1 (210) is executed first, followed by command 2 (212), and so on through command N (216). The command counter 124 of can track which command within the currently executing sequence is being processed.

Each command can have an associated command number 218, a command length 220, and command data 222. The command number 218 can identify the command within the sequence. The command length 220 can specify a number of bytes of data associated with the command. In an example, the command length 220 can specify a number of bytes to be written to or read from the one or more peripheral battery management devices 112 for that command. The command data 222 can include the data payload associated with the command.

Each command can be either a read command or a write command. For a write command having a nonzero command length 220, the command data 222 can include one or more bytes of data to be written to the one or more peripheral battery management devices 112, such as register values to be written to a register of one or more peripheral battery management devices 112. For a write command having a command length 220 of zero, the command can consist of a command code and an associated error-checking value (e.g., a packet error code (PEC) or cyclic redundancy check (CRC)) without any accompanying data payload. Such a zero-length write command can be used, for example, to instruct a peripheral battery management device 112 to enter a sleep mode, to initiate a measurement cycle, or to perform another operation that does not require a data payload.

For a read command, after the command code and error-checking value have been transmitted to the one or more peripheral battery management devices 112, the peripheral battery management devices 112 can return response data. The sequence controller 104 can receive the response data via the second communication interface 110 and store the received data in the read data area 146 of the memory 118. In an example, the received data can be stored in a region of the read data area 146 corresponding to a data type identifier associated with the read command. The data type identifier can indicate a category of data, such as a cell voltage type, a cell current type, a temperature type, or a diagnostic type. The data type identifier can be specified in a command header stored in the sequence command area 120 of the memory 118. The control unit 106 can subsequently request data of a particular type from the memory 118 via the first communication interface 108, and the bridge circuit 102 can return the stored data corresponding to the requested type.

In an example, each command can also include a command code that identifies the operation to be performed by the one or more peripheral battery management devices 112. The command code can indicate whether the command is a read command or a write command. In an example, a bit within the command code can be set to a first value (e.g., logic 1) to indicate a read command and to a second value (e.g., logic 0) to indicate a write command. The one or more peripheral battery management devices 112 can decode the command code to determine the operation to be performed. For a read command, the peripheral battery management device 112 can switch its communication interface from a receiving mode to a transmitting mode and return the requested data. For a write command, the peripheral battery management device 112 can remain in the receiving mode and accept the command data 222 that follows the command code.

In an example, a first command in a sequence can be a write command that configures one or more of the peripheral battery management devices 112 for a particular measurement mode (e.g., enabling odd-channel or even-channel internal switches for open wire detection), and a subsequent command in the same or other sequence can be a read command that retrieves measurement data from the peripheral battery management devices 112 after the configuration has taken effect (e.g., and the measurement parameters are settled). In this way, a single sequence can implement a multi-step measurement or diagnostic procedure by combining write and read commands in a prescribed order.

In another example, a first sequence can include one or more read commands for periodically reading cell voltage data from the peripheral battery management devices 112, and a second sequence can include one or more read commands for periodically reading cell current data. The first sequence and the second sequence can have different execution periods, as determined by their respective skip parameters (e.g., as discussed below), such that cell voltage data is read at a first interval and cell current data is read at a second, different interval. In yet another example, a sequence can include a series of read commands, each directed to a different parameter (e.g., a first command to read cell voltages, a second command to read cell currents, a third command to read temperatures), such that all parameters are read in a single execution of the sequence, or at least part in two or more sequences (e.g., there may be to many read commands to fit into a single sequence).

FIG. 3 shows a block diagram of an example of a sequence mask register 312 and a sequence ready list 314 that can be used by the sequence controller 104 of FIG. 1. FIG. 3 shows that each sequence of the plurality of sequences can have an associated ready status. For example, sequence 1 (SEQ1) 202 can have a sequence 1 ready bit 306, sequence 31 (SEQ31) 302 can have a sequence 31 ready bit 308, and sequence 32 (SEQ32) 304 can have a sequence 32 ready bit 310. Although FIG. 3 shows three sequences by way of example, any number of sequences can have an associated ready status, such as can include 8, 16, 32, 64, or any other number.

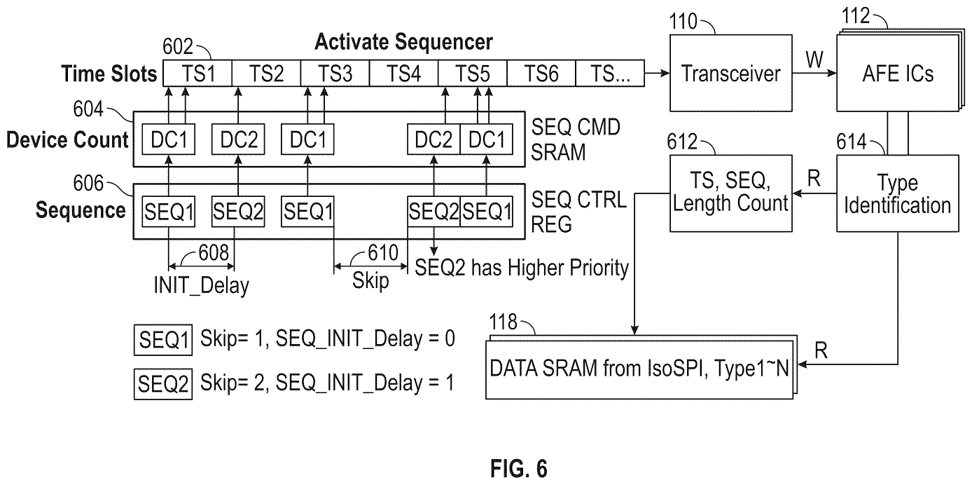

The ready status of each sequence can be determined by the sequence controller 104 based on one or more parameters associated with the sequence. In an example, the sequence controller 104 can compare the current time slot number (e.g., as tracked by the time slots counter 122 of FIG. 1) with one or more timing parameters associated with the sequence, such as can include an initial delay parameter and a skip parameter, to determine whether the sequence is due for execution in the current time slot. The initial delay parameter and the skip parameter can be discussed in more detail below with respect to FIG. 6.

The sequence mask register 312 can be a register having a plurality of bits. FIG. 3 shows the sequence mask register 312 as a 32-bit register with bit positions 31 through 0. Each bit of the sequence mask register 312 can correspond to a respective sequence of the plurality of sequences. When a bit in the sequence mask register 312 is set to a first value (e.g., logic 1), the corresponding sequence can be prevented from appearing as ready in the sequence ready list 314, regardless of whether the sequence would otherwise be ready for execution based on its timing parameters. When a bit in the sequence mask register 312 is set to a second value (e.g., logic 0), the corresponding sequence can be permitted to appear as ready in the sequence ready list 314 if its timing parameters indicate that it is due for execution. In other examples, the polarity of the mask bits can be reversed, such that a logic 0 masks a sequence and a logic 1 permits a sequence. In still other examples, the sequence mask register 312 can have any other number of bits, such as can include 8, 16, 64, or any other number corresponding to the number of sequences supported.

The sequence ready list 314 can be a register having a plurality of bits. FIG. 3 shows the sequence ready list 314 as a 32-bit register with bit positions 31 through 0, with bit 31 labeled as the most significant bit (MSB) and bit 0 labeled as the least significant bit (LSB). Each bit of the sequence ready list 314 can correspond to a respective sequence of the plurality of sequences. A bit in the sequence ready list 314 can be asserted (e.g., set to logic 1) when the corresponding sequence is ready for execution in the current time slot and is not masked by the corresponding bit in the sequence mask register 312. A bit in the sequence ready list 314 can be deasserted (e.g., set to logic 0) when the corresponding sequence is not ready for execution or is masked.

FIG. 3 shows lines extending from the ready bits 306, 308, 310 of the respective sequences through the sequence mask register 312 to corresponding bit positions of the sequence ready list 314. This can represent a filtering operation in which the ready status of each sequence is gated by the corresponding bit of the sequence mask register 312 before being reflected in the sequence ready list 314. In an example, the filtering operation can include a logical XOR between the ready status of the sequence and the complement of the corresponding mask bit, such that the sequence appears as ready in the sequence ready list 314 only if the sequence is due for execution and the corresponding mask bit is not asserted. In other examples, any other logical operation or combination of operations can be used.

In an example, each sequence of the plurality of sequences can have an associated priority. The priority can be determined by the bit position of the sequence in the sequence ready list 314. For example, a sequence corresponding to a higher bit position (e.g., closer to the MSB, bit 31) can have a higher priority than a sequence corresponding to a lower bit position (e.g., closer to the LSB, bit 0). The sequence controller 104 can select a ready sequence having a highest priority from the sequence ready list 314 for execution by iterating over the sequence ready list 314, such as by checking from the MSB toward the LSB and selecting the first asserted bit encountered. In other examples, the priority can be determined by a separate priority value stored in a sequence control register associated with each sequence, by a priority field within the sequence data stored in the memory 118, or by any other mechanism.

The sequence ready list 314 can be updated at one or more times, such as can include when a new time slot begins, when the sequence mask register 312 is changed, or when a sequence completes execution. In an example, the sequence controller 104 can refresh the sequence ready list 314 at the beginning of each time slot by evaluating the timing parameters and mask status of each sequence. In another example, modifying the sequence mask register 312 during a time slot can trigger an update of the sequence ready list 314 within the same time slot, such that a newly unmasked sequence can become eligible for execution without waiting for the next time slot boundary.

The control unit 106 can modify the sequence mask register 312 during runtime via the first communication interface 108, such as to dynamically enable or disable individual sequences without halting the sequence controller 104. In an example, the control unit 106 can set one or more bits in the sequence mask register 312 to prevent one or more sequences from executing, such as when the control unit 106 determines that a particular measurement or diagnostic routine is not needed during a current operating mode. In another example, the control unit 106 can clear one or more bits in the sequence mask register 312 to enable one or more sequences that were previously disabled, such as when the control unit 106 determines that a particular measurement or diagnostic routine is needed. This can help to allow the control unit 106 to adjust the set of active sequences during runtime, such as without reloading the sequence data in the memory 118.

In an example, the control unit 106 can use the sequence mask register 312 to inject an emergency sequence. The control unit 106 can load the emergency sequence into the memory 118 during runtime while the sequence controller 104 is executing other sequences. The emergency sequence can initially be masked by setting the corresponding bit in the sequence mask register 312 to the first value (e.g., logic 1) while the emergency sequence data is being written to the memory 118. After the emergency sequence data has been loaded into the memory 118, the control unit 106 can clear the corresponding bit in the sequence mask register 312, causing the sequence ready list 314 to be updated and the emergency sequence to appear as ready. The emergency sequence can be assigned a bit position in the sequence ready list 314 corresponding to a highest priority (e.g., the MSB or a bit position higher than any other active sequence), such that the sequence controller 104 selects the emergency sequence for execution the next time the sequence ready list 314 is checked. In an example, the emergency sequence can be executed after completion of a currently executing sequence and before any other ready sequence in the sequence ready list 314.

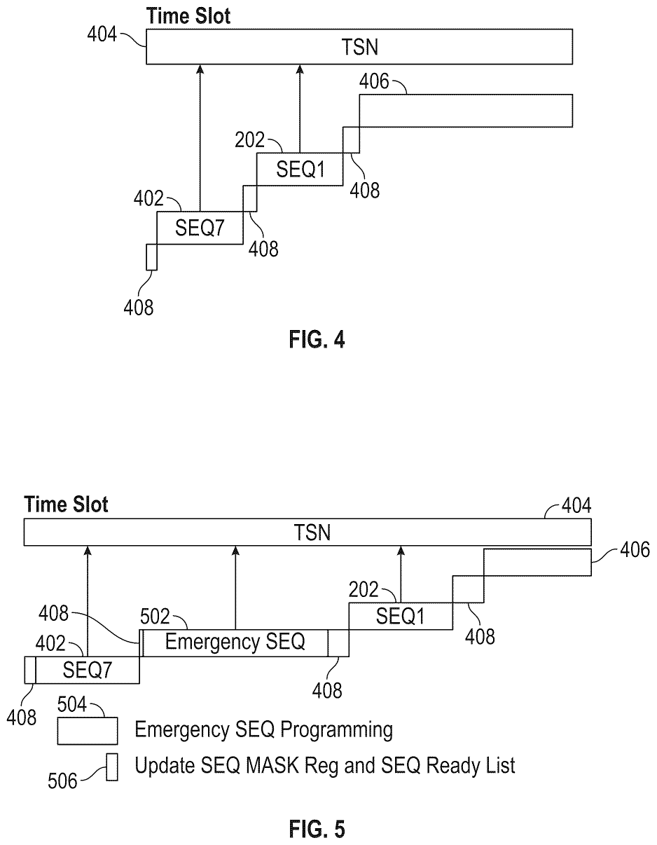

FIG. 4 shows a timing diagram of an example of a sequence execution order, such as within a single time slot, such as can be managed by the sequence controller 104. FIG. 4 shows a time slot 404 spanning a duration labeled TSN. The time slot 404 can represent one of the discrete time slots generated by the time slots generator 126. The duration of the time slot 404 can be configurable, such as can include a duration on the order of microseconds (e.g., 1 microsecond, 10 microseconds, 50 microseconds, 100 microseconds, or any other duration). In other examples, the duration can be on the order of milliseconds or any other time unit. One or more time slots can be configured to have the same duration, or one or more time slots can differ in duration.

FIG. 4 shows that within the time slot 404, the sequence controller 104 can execute one or more sequences in a priority order. In the example of FIG. 4, two sequences are ready for execution: sequence 7 (SEQ7) 402 and sequence 1 (SEQ1) 202. Sequence 7 (402) can have a higher priority than sequence 1 (202), such as can be determined by the bit position of each sequence in the sequence ready list 314 of FIG. 3 (e.g., sequence 7 can correspond to a higher bit position than sequence 1) or by any other priority mechanism.

At the beginning of the time slot 404, the sequence controller 104 can perform a ready list check 408. During the ready list check 408, the sequence controller 104 can examine the sequence ready list 314 to determine which sequences are ready for execution in the current time slot. The sequence controller 104 can iterate over the sequence ready list 314, such as by checking from the most significant bit (MSB) toward the least significant bit (LSB), and can select the first asserted bit encountered, which can correspond to the ready sequence with the highest priority. In the example of FIG. 4, the sequence controller 104 can determine that both sequence 7 (402) and sequence 1 (202) are ready, and can select sequence 7 (402) for execution first because sequence 7 (402) has a higher priority.

FIG. 4 shows that after the ready list check 408, sequence 7 (402) can be executed. During execution of sequence 7 (402), the sequence controller 104 can retrieve the one or more commands associated with sequence 7 (402) from the memory 118 and can transmit the retrieved commands to the one or more peripheral battery management devices 112 using the second communication interface 110, such as described above with respect to FIG. 1. For read commands within sequence 7 (402), the sequence controller 104 can store data received from the one or more peripheral battery management devices 112 in the memory 118.

After sequence 7 (402) completes execution another ready list check 408 can take place. During this ready list check 408, the sequence controller 104 can examine the sequence ready list 314 to determine whether any additional sequences remain ready for execution in the current time slot. In the example of FIG. 4, the sequence controller 104 can determine that sequence 1 (202) remains ready and can select sequence 1 (202) for execution. The sequence controller 104 can then retrieve and execute the one or more commands associated with sequence 1 (202) in the same manner as described above for sequence 7 (402).

After sequence 1 (202) completes execution, FIG. 4 shows another ready list check 408. During this ready list check 408, the sequence controller 104 can determine that no additional sequences remain ready for execution in the current time slot. FIG. 4 shows a sleep time 406 following the final ready list check 408, extending to the end of the time slot 404. The sequence controller 104 can be configured to enter a low-power mode during the sleep time 406 when no remaining sequences are ready for execution in the current time slot. In the low-power mode, the sequence controller 104 can reduce or cease activity, such as can include one or more of gating one or more clock signals, reducing a clock frequency, or placing one or more circuit blocks in a reduced-power state, such as until the next time slot begins.

Although FIG. 4 shows two sequences being executed within a single time slot by way of example, any number of sequences can be executed within a single time slot, such as can include one, three, four, five, or more sequences, depending on how many sequences are ready for execution and the time available within the time slot. In an example, if only one sequence is ready for execution in a given time slot, the sequence controller 104 can execute that one sequence and then enter the low-power mode for the remainder of the time slot. In another example, if no sequences are ready for execution in a given time slot, the sequence controller 104 can enter the low-power mode for the entire duration of the time slot.

In an example, a sequence can take longer to execute than the remaining time in the current time slot. In such a case, the sequence controller 104 can continue executing the sequence into the next time slot, such that the sequence completes before the sequence controller 104 checks the sequence ready list 314 for the next time slot. This can result in a delay of one or more subsequent sequences that would otherwise have been ready for execution at the beginning of the next time slot. In an example, a configuration tool can be provided to a user (e.g., the control unit 106 or a developer configuring the system) to verify that the sequences assigned to a given time slot can complete within the allocated time slot duration, such as to help reduce or avoid time slot overruns during normal operation.

FIG. 4 shows that the ready list check 408 can occur at multiple points within a time slot: at the beginning of the time slot, after each sequence completes execution, and before entering the low-power mode. In other examples, the ready list check 408 can occur at fewer or more points within a time slot, such as can include only at the beginning of the time slot, at periodic intervals within the time slot, or at any other time. The sequence controller 104 can use the ready list check 408 to determine whether a newly ready sequence (e.g., an emergency sequence that has been unmasked during the time slot, as discussed below with respect to FIG. 5) should be executed before any remaining lower-priority sequences.

FIG. 5 shows a timing diagram of an example of an emergency sequence injection process, such as can be performed by the battery management system 100. The timing diagram shows a time slot 404, which can represent one of the discrete time slots generated by the time slots generator 126. The process can allow the control unit 106 to inject a emergency sequence 502 (e.g., a high priority sequence) into the execution flow of the sequence controller 104 during runtime, such as without halting or rebooting the bridge circuit 102.

The timing diagram begins with the execution of a regular, non-emergency sequence, sequence 7 (SEQ7) 402, within the time slot 404. While sequence 7 (402) is executing, the control unit 106 can initiate the injection of an emergency sequence 502. In an example, the control unit 106 can load the emergency sequence 502 into the memory 118, such as using the first communication interface 108. The emergency sequence 502 can include one or more commands for the one or more peripheral battery management devices 112, such as commands to disconnect a battery pack, open contactors, or place the peripheral battery management devices 112 into a safe state in response to a fault condition (e.g., a vehicle collision, a thermal runaway event, or a critical diagnostic failure detected by the control unit 106).

In an example, the emergency sequence 502 can be loaded into a designated area of the sequence command area 120 of the memory 118, such as at load emergency sequence 504. While the emergency sequence 502 is being loaded, the corresponding bit in the sequence mask register 312 can be set to a first value (e.g., logic 1) to prevent the sequence controller 104 from attempting to execute an incomplete sequence.

After the control unit 106 has finished loading the emergency sequence 502 into the memory 118, the control unit 106 can update the sequence mask register 312 and the sequence ready list 314, as shown by step 506. This update can include clearing the mask bit corresponding to the emergency sequence 502 in the sequence mask register 312 (e.g., changing the bit from logic 1 to logic 0). This action can cause the sequence ready list 314 to be refreshed, and if the emergency sequence 502 is configured to be ready (e.g., it has no unmet timing dependencies), its corresponding bit in the sequence ready list 314 can be asserted.

The emergency sequence 502 can be assigned a priority that is higher than any other sequence. In an example, the emergency sequence 502 can correspond to the most significant bit (MSB) of the sequence ready list 314 or another bit position corresponding to a highest priority.

After sequence 7 (402) completes its execution, the sequence controller 104 can check the sequence ready list 314 to select the next sequence to execute. Because the emergency sequence 502 is now ready and has the highest priority, the sequence controller 104 can select the emergency sequence 502 for execution ahead of any other ready sequences, such as sequence 1 (SEQ1) 202. The sequence controller 104 can then retrieve the one or more commands associated with the emergency sequence 502 from the memory 118 and transmit them to the one or more peripheral battery management devices 112.

After the emergency sequence 502 has completed execution, the sequence controller 104 can again check the sequence ready list 314. In the example of FIG. 5, sequence 1 (202) is also ready for execution. The sequence controller 104 can select sequence 1 (202) and proceed with its execution. This injection mechanism can help to provide a quick response to critical events, with the emergency sequence 502 being executed after a latency that can be on the order of the time required to complete a currently executing command or sequence. The sequence controller 104 can be configured to execute the emergency sequence 502 the next time the sequence ready list 314 is checked after the corresponding mask bit has been cleared.

In an example, the memory 118 can include a designated emergency sequence location that is separate from the locations used for the plurality of sequences (e.g., SEQ1 202 through SEQM 206). The control unit 106 can load the emergency sequence into the designated emergency sequence location using the first communication interface 108 during runtime while the sequence controller 104 is executing other sequences. After the emergency sequence has been loaded into the designated emergency sequence location, the control unit 106 can set an emergency flag in the sequence controller 104, such as by writing to a control register accessible via the first communication interface 108. In response to the emergency flag being set, the sequence controller 104 can clear the sequence mask register 312, such as by setting all bits of the sequence mask register 312 to a value (e.g., logic 1) that prevents all non-emergency sequences from appearing as ready in the sequence ready list 314. The sequence controller 104 can then update the sequence ready list 314 such that only the emergency sequence appears as ready. At the next ready list check 408, the sequence controller 104 can select the emergency sequence for execution. Because all non-emergency sequences have been masked, the emergency sequence can be the only sequence eligible for selection, regardless of the priority assignments of the other sequences. After the emergency sequence has been executed, the control unit 106 can restore the sequence mask register 312 to its previous state, such as to resume normal sequence execution, or the control unit 106 can leave the non-emergency sequences masked, such as when the system is to remain in a safe state following the emergency event.

FIG. 6 shows a block diagram showing an example of the operation of the sequence controller 104, such as over a series of time slots 602, such as including the interaction between the sequence controller 104, the second communication interface 110, and the one or more peripheral battery management devices 112. FIG. 6 shows that the sequence controller 104 can divide time into discrete time slots 602 with a specified slot length. FIG. 6 shows an example including time slots TS1, TS2, TS3, TS4, TS5, TS6, and subsequent time slots “TS . . . ”.

One or more of time slot of the time slots 602 can be associated with a device count 604 and a sequence 606. The device count 604 can indicate a number of peripheral battery management devices 112 to be addressed during the associated time slot. FIG. 6 shows two example device counts, DC1 and DC2, though in other examples any device count value can be used, such as can include values ranging from 1 to 32, or any other value. In an example, different time slots can have different device counts, such as when different sequences address different numbers of peripheral battery management devices 112. In another example, all time slots can have the same device count.

FIG. 6 shows two sequences, SEQ1 and SEQ2, stored in a sequence command memory (SEQ CMD SRAM) and associated with sequence control registers (SEQ CTRL REG). Each sequence of the plurality of sequences can have an associated initial delay parameter 608 and an associated skip parameter 610. The initial delay parameter 608 can specify a number of time slots following initialization of the sequence controller 104 before the first execution of the associated sequence. The skip parameter 610 can specify a number of time slots between successive executions of the associated sequence. In an example, the initial delay parameter 608 and the skip parameter 610 can be expressed in units of time slots. In other examples, the initial delay parameter 608 and the skip parameter 610 can be expressed in other units, such as can include clock cycles, microseconds, milliseconds, or any other time unit.

FIG. 6 shows that SEQ1 can have a skip parameter value of 1 and an initial delay parameter value of 0 (Skip=1, SEQ_INIT_Delay=0). Because the initial delay parameter of SEQ1 is 0, SEQ1 can be ready for execution beginning at the first time slot TS1 following activation of the sequence controller 104. Because the skip parameter of SEQ1 is 1, there can be one time slot between successive executions of SEQ1. Accordingly, FIG. 6 shows SEQ1 executing in TS1, TS3, and TS5, with one intervening time slot between each execution (e.g., TS2 between TS1 and TS3, TS4 between TS3 and TS5). In other examples, the skip parameter can be any non-negative integer, such as can include 0 (indicating execution in every time slot), 2, 3, 5, 10, 50, 100, or any other value.

FIG. 6 shows that SEQ2 can have a skip parameter value of 2 and an initial delay parameter value of 1 (Skip=2, SEQ_INIT_Delay=1). Because the initial delay parameter of SEQ2 is 1, SEQ2 can be not ready for execution in the first time slot TS1 and can be ready for execution beginning at the second time slot TS2. Because the skip parameter of SEQ2 is 2, there can be two time slots between successive executions of SEQ2. Accordingly, FIG. 6 shows SEQ2 executing in TS2 and TS4, with two intervening time slots between each execution (e.g., TS3 and the portion of TS4 before SEQ2 executes). The next execution of SEQ2 after TS4 can occur at a subsequent time slot determined by the skip parameter.

FIG. 6 shows that in TS5, both SEQ1 and SEQ2 can be ready for execution in the same time slot. Each sequence of the plurality of sequences can have an associated priority. FIG. 6 indicates that SEQ2 has a higher priority than SEQ1. When multiple sequences are ready for execution in the same time slot, the sequence controller 104 can select a ready sequence having a highest priority from the sequence ready list 128 for execution. In the example of FIG. 6, in TS5, the sequence controller 104 can select SEQ2 for execution before SEQ1, such as because SEQ2 has a higher priority. After SEQ2 completes execution, the sequence controller 104 can check the sequence ready list 128 again and can select SEQ1 for execution if SEQ1 remains ready.

In an example, the initial delay parameter 608 and the skip parameter 610 can be used together to implement multi-step measurement or diagnostic procedures that span multiple time slots. For example, a first sequence can have an initial delay parameter of 0 and a skip parameter of 4, and a second sequence can have an initial delay parameter of 2 and a skip parameter of 4. The first sequence can include a write command that configures the peripheral battery management devices 112 for a measurement mode (e.g., enabling odd-channel internal switches for open wire detection), and the second sequence can include a read command that retrieves measurement data after the configuration has taken effect. Because the second sequence has an initial delay that is 2 time slots later than the first sequence, the peripheral battery management devices 112 can have time to settle into the configured measurement mode before the measurement data is read. Both sequences can repeat with the same skip parameter, such that the multi-step procedure is executed periodically. In other examples, any number of sequences can be coordinated using different combinations of initial delay and skip parameter values to implement procedures of any number of steps.

FIG. 6 also shows the data flow between the sequence controller 104, the second communication interface 110, the one or more peripheral battery management devices 112, and the memory 118. The second communication interface 110 can be labeled as a transceiver in FIG. 6. The one or more peripheral battery management devices 112 can include one or more analog front-end (AFE) ICs, though in other examples the peripheral battery management devices 112 can include any other type of device, such as can include power management circuits, temperature sensors, or any other monitoring or control device.

FIG. 6 shows a write path (labeled W) from the transceiver 110 to the AFE ICs 112 and a read path (labeled R) from the AFE ICs 112 back through the transceiver 110. For a write command, the sequence controller 104 can retrieve the command data from the sequence command area 120 in the memory 118, and the second communication interface 110 can transmit the command to the one or more peripheral battery management devices 112 over the write path. For a read command, after the command code has been transmitted to the one or more peripheral battery management devices 112, the peripheral battery management devices 112 can return response data over the read path through the second communication interface 110.

FIG. 6 shows a parameters block 612 labeled that can store or track parameters associated with the current operation, such as can include the current time slot number, the currently executing sequence identifier, and a length count indicating a number of bytes being read from or written to the peripheral battery management devices 112. The sequence controller 104 can use these parameters to manage the transfer of data between the memory 118 and the second communication interface 110.

FIG. 6 shows a type identification block 614 that can identify a data type associated with a read command. The data type can indicate a category of data returned by the peripheral battery management devices 112, such as can include a cell voltage type, a cell current type, a temperature type, a diagnostic type (e.g., open wire detection data), a balance voltage type, or any other category. The type identification block 614 can direct the received data to a corresponding region of the memory 118 based on the identified data type. FIG. 6 shows a read path (labeled R) from the type identification block 614 to a data SRAM region 118 labeled “DATA SRAM from IsoSPI, Type1~N,” indicating that the received data can be stored in one of N type-specific regions in the memory 118. In an example, N can be any positive integer, such as can include 1, 2, 4, 8, 12, 16, or any other value. The data type identifier can be specified in a command header stored in the sequence command memory of the memory 118, such as in a field of the command header associated with each command.

In an example, the control unit 106 can subsequently request data of a particular type from the memory 118 via the first communication interface 108. The bridge circuit 102 can return the stored data from the type-specific region of the memory 118 corresponding to the requested type. Because the data is organized by type in the memory 118, the control unit 106 can request data by type, such as without needing to know which specific command or sequence produced the data. In an example, the control unit 106 can issue a single request for a particular data type (e.g., cell voltage), and the bridge circuit 102 can return the data for all peripheral battery management devices 112 of that type, such as can include cell voltage data for all cells monitored by all AFE ICs in the daisy chain. This can reduce the number of transactions on the first bus 114 between the control unit 106 and the bridge circuit 102 as compared to an approach in which the control unit 106 requests data from each peripheral battery management device 112 individually.

In an example, the plurality of sequences can be loaded into the memory 118 by the control unit 106 using the first communication interface 108 during a configuration phase. During the configuration phase, the control unit 106 can write the sequence commands, command data, initial delay parameters 608, skip parameters 610, device counts 604, type identifiers, and other configuration data to the sequence command memory and the sequence control registers in the memory 118. After the configuration phase, during runtime, the sequence controller 104 can execute the sequences without further intervention from the control unit 106. The sequence controller 104 can use the stored initial delay parameters 608 and skip parameters 610 to determine when each sequence is due for execution, can use the stored device counts 604 to determine how many peripheral battery management devices 112 to address, and can use the stored type identifiers to direct received data to the corresponding type-specific regions of the memory 118. The control unit 106 can read the stored data from the memory 118 asynchronously with respect to the operations of the sequence controller 104, such as at any time and at any frequency determined by the control unit 106.

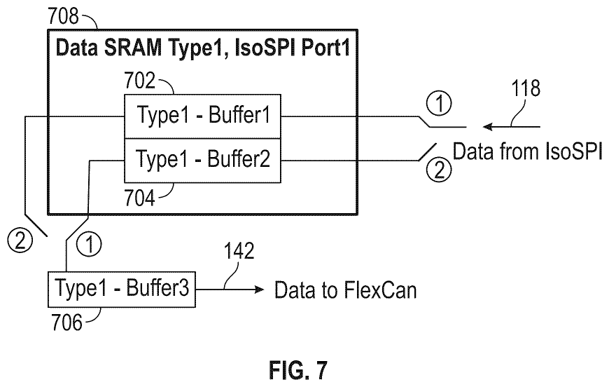

FIG. 7 shows a block diagram of an example of a buffer structure within the memory 118, such as for managing data received from the one or more peripheral battery management devices 112 via the second communication interface 110. FIG. 7 shows a ping-pong buffer 708, which can represent a type-specific region of the memory 118 allocated to a first data type (e.g., cell voltage data) associated with a first isoSPI port of the second communication interface 110. In other examples, the memory 118 can include additional type-specific regions for other data types (e.g., cell current, temperature, diagnostic data, balance voltage, or any other category) and for other isoSPI ports, such as when the second communication interface 110 includes two or more transceiver ports.

FIG. 7 shows that the ping-pong buffer 708 can include a data type 1 buffer 1 702 and a data type 1 buffer 2 704 arranged within the ping-pong buffer 708. FIG. 7 also shows a data type 1 buffer 3 706 positioned outside the ping-pong buffer 708. Incoming data from the second communication interface 110 can be directed to either the data type 1 buffer 1 702 or the data type 1 buffer 2 704, as determined by the position of a buffer switch. Outgoing data to the control unit 106 via the first communication interface 108 is can be provided from the data type 1 buffer 3 706 over the communication bus 142.

The data type 1 buffer 1 702 and data type 1 buffer 2 704 can operate as a ping-pong pair within the ping-pong buffer 708. In this arrangement, incoming data from the second communication interface 110 can be directed to one of the two buffers at a time. For example, data received from the one or more peripheral battery management devices 112 in response to a read command can initially be stored in the data type 1 buffer 1 702. When the data type 1 buffer 1 702 is full (e.g., when all expected response data for the current execution of the associated command or sequence has been received), subsequent incoming data can be directed to the data type 1 buffer 2 704. When the data type 1 buffer 2 704 is full, subsequent incoming data can be directed back to the data type 1 buffer 1 702. In this way, the two buffers can alternate in receiving incoming data. In other examples, the switching between the data type 1 buffer 1 702 and the data type 1 buffer 2 704 can be triggered by other conditions, such as can include the completion of a sequence execution, the expiration of a timer, or any other event.

FIG. 7 shows that data from either the data type 1 buffer 1 702 or the data type 1 buffer 2 704 can be copied to the data type 1 buffer 3 706. When one of the buffers within the ping-pong buffer 708 (e.g., the data type 1 buffer 1 702 or the data type 1 buffer 2 704) becomes full and contains a complete set of received data, the contents of that buffer can be copied to the data type 1 buffer 3 706. The data type 1 buffer 3 706 can then hold the newest complete set of received data of the associated data type. The control unit 106 can read from the data type 1 buffer 3 706 via the communication bus 142 using the first communication interface 108.

This three-buffer arrangement can help to allow the control unit 106 to read stored data from the memory 118 asynchronously with respect to the storage of received data from the one or more peripheral battery management devices 112. Because the control unit 106 reads from the data type 1 buffer 3 706 and the incoming data from the second communication interface 110 is written to the data type 1 buffer 1 702 or the data type 1 buffer 2 704, the read and write operations can occur without interfering with each other. The received data can be stored in whichever buffer within the ping-pong buffer 708 contains the oldest data, and the buffer within the ping-pong buffer 708 containing the newest complete data can be copied to the data type 1 buffer 3 706, which can serve as a read buffer. The control unit 106 can read from the data type 1 buffer 3 706 containing the newest available data.

In an example, the data type 1 buffer 3 706 can be configured such that data from the ping-pong buffer 708 containing the newest data will not be written to the data type 1 buffer 3 706 when the control unit 106 is reading from the data type 1 buffer 3 706. This can help to prevent the control unit 106 from reading partially updated data. In an example, the sequence controller 104 can monitor a status of the communication bus 142 or a read request from the first communication interface 108, and can delay the copy operation from the ping-pong buffer 708 to the data type 1 buffer 3 706 until the control unit 106 has completed its read operation. In another example, a hardware lock or flag can be used to indicate that the data type 1 buffer 3 706 is being read by the control unit 106, and the sequence controller 104 can defer the copy operation until the lock or flag is released. In an example, the copy operation can be gated by a clock cycle or a bus arbitration mechanism. In other examples, any other mechanism can be used to coordinate the copy operation and the read operation on the data type 1 buffer 3 706.

In an example where only two buffers are used (e.g., without the data type 1 buffer 3 706), the received data can be stored in a first buffer and the control unit 106 can read from a second buffer containing the newest data. The buffer being read can be write-locked or a notification can be sent to the control unit 106 if a write to the buffer occurs during a read operation.

Although FIG. 7 shows a single data type (Type1) and a single isoSPI port by way of example, the memory 118 can include a similar three-buffer structure for one or more (e.g., each) data type and each isoSPI port supported by the bridge circuit 102. In an example, if the bridge circuit 102 supports N data types and P isoSPI ports, the memory 118 can include N times P sets of three buffers. In other examples, one or more data types can share a buffer structure, or one or more data types can use a different number of buffers (e.g., two buffers or four or more buffers).

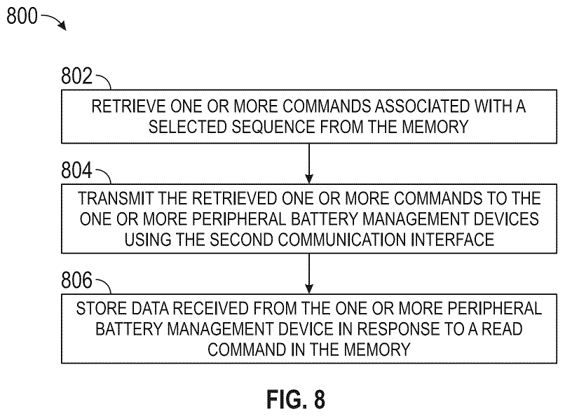

FIG. 8 shows an example of portions of a method 800 for operating a bridge circuit, such as the bridge circuit 102. At step 802, the method 800 can include retrieving, using the sequence controller 104, one or more commands associated with a selected sequence from the memory 118. The sequence controller 104 can read command headers, command codes, error-checking values (e.g., CRC values), and command data for the one or more commands from the sequence command area 120 of the memory 118. In an example, the selected sequence can be selected based on a priority associated with the selected sequence, such as by selecting a ready sequence having a highest priority from the sequence ready list 128. In another example, the selected sequence can be selected based on a position of the selected sequence in the sequence ready list 128, such as by iterating from a most significant bit toward a least significant bit and selecting the first asserted bit encountered. In an example, the command counter 124 can track which command within the selected sequence is being processed. In an example, the sequence controller 104 can load the command code, error-checking value, and command data into the FIFO buffer 136 for transmission.

At step 804, the method 800 can include transmitting, using the second communication interface 110, the retrieved one or more commands to the one or more peripheral battery management devices 112. The one or more commands can include write commands, read commands, or a combination thereof, and can propagate through the one or more peripheral battery management devices 112 via the second bus 116.

At step 806, the method 800 can include storing, using the sequence controller 104, data received from the one or more peripheral battery management devices 112 in response to a read command in the memory 118. The received data can be directed through the second communication interface 110 and the FIFO buffer 136 to a region of the read data area 146 of the memory 118 corresponding to a data type identifier associated with the read command. In an example, step 806 can be omitted for a sequence that includes only write commands.

In an example, the method 800 can also include, such as prior to step 802, loading the plurality of sequences into the memory 118 using the first communication interface 108 during a configuration phase. After the configuration phase, during runtime, the sequence controller 104 can execute the sequences by performing steps 802, 804, and 806 without further intervention from the control unit 106.

In an example, the method 800 can also include, during runtime following the configuration phase, loading an emergency sequence into the memory 118 using the first communication interface 108, and executing the emergency sequence the next time the sequence ready list 128 is checked by the sequence controller 104.

The shown order of steps in FIG. 8 is not intended to be a limitation on the order the steps are performed in. In an example, two or more steps can be performed simultaneously or at least partially concurrently. In an example, step 806 can be omitted for a sequence that includes only write commands and no read commands, such that the method 800 includes steps 802 and 804 without step 806. In an example, the method 800 can be performed repeatedly as the sequence controller 104 cycles through successive time slots and successive sequences within each time slot.

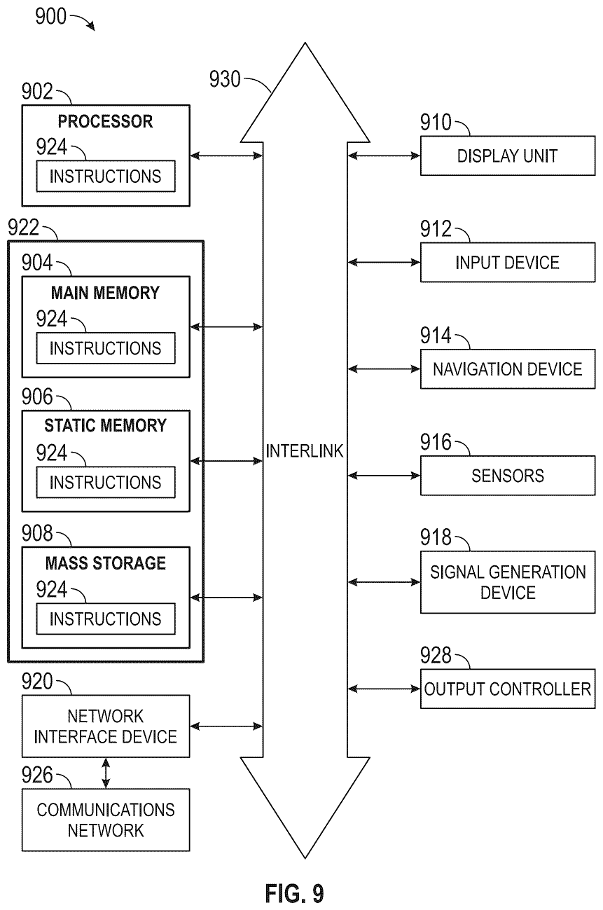

FIG. 9 illustrates a block diagram of an example machine 900 upon which any one or more of the techniques (e.g., methodologies) discussed herein may be implemented. Examples, as described herein, may include, or may operate by, logic or a number of components, or mechanisms in the machine 900. Circuitry (e.g., processing circuitry) is a collection of circuits implemented in tangible entities of the machine 900 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 900 follow.

In alternative examples, the machine 900 may operate as a standalone device or may be connected (e.g., networked) to other machines. In a networked deployment, the machine 900 may operate in the capacity of a server machine, a client machine, or both in server-client network environments. In an example, the machine 900 may act as a peer machine in peer-to-peer (P2P) (or other distributed) network environment. The machine 900 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 900 may include a hardware processor 902 (e.g., a central processing unit (CPU), a graphics processing unit (GPU), a hardware processor core, or any combination thereof), a main memory 904, a static memory (e.g., memory or storage for firmware, microcode, a basic-input-output (BIOS)), and mass storage 908 (e.g., hard drives, tape drives, flash storage, or other block devices) some or all of which may communicate with each other via an interlink 930 (e.g., bus). The machine 900 may further include a display unit 910, an alphanumeric input device 912 (e.g., a keyboard), and a user interface (UI) navigation device 914 (e.g., a mouse). In an example, the display unit 910, input device 912 and UI navigation device 914 may be a touch screen display. The machine 900 may additionally include a signal generation device 918 (e.g., a speaker), a network interface device 920, and one or more sensors 916, such as a global positioning system (GPS) sensor, compass, accelerometer, or other sensor. The machine 900 may include an output controller 928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 902, the main memory 904, the static memory 906, or the mass storage 908 may be, or include, a machine readable medium 922 on which is stored one or more sets of data structures or instructions 924 (e.g., software) embodying or utilized by any one or more of the techniques or functions described herein. The instructions 924 may also reside, completely or at least partially, within any of registers of the processor 902, the main memory 904, the static memory 906, or the mass storage 908 during execution thereof by the machine 900. In an example, one or any combination of the hardware processor 902, the main memory 904, the static memory 906, or the mass storage 908 may constitute the machine readable media 922. While the machine readable medium 922 is illustrated as a single medium, the term “machine readable medium” may include a single medium or multiple media (e.g., a centralized or distributed database, and/or associated caches and servers) configured to store the one or more instructions 924.

The term “machine readable medium” may include any medium that is capable of storing, encoding, or carrying instructions for execution by the machine 900 and that cause the machine 900 to perform any one or more of the techniques of the present disclosure, or that is capable of storing, encoding or carrying data structures used by or associated with such instructions. Non-limiting machine readable medium examples may include solid-state memories, optical media, magnetic media, and signals (e.g., radio frequency signals, other photon based signals, sound signals, etc.). In an example, a non-transitory machine readable medium comprises a machine readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 922 may be representative of the instructions 924, such as instructions 924 themselves or a format from which the instructions 924 may be derived. This format from which the instructions 924 may be derived may include source code, encoded instructions (e.g., in compressed or encrypted form), packaged instructions (e.g., split into multiple packages), or the like. The information representative of the instructions 924 in the machine readable medium 922 may be processed by processing circuitry into the instructions to implement any of the operations discussed herein. For example, deriving the instructions 924 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 924.

In an example, the derivation of the instructions 924 may include assembly, compilation, or interpretation of the information (e.g., by the processing circuitry) to create the instructions 924 from some intermediate or preprocessed format provided by the machine readable medium 922. The information, when provided in multiple parts, may be combined, unpacked, and modified to create the instructions 924. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 924 may be further transmitted or received over a communications network 926 using a transmission medium via the network interface device 920 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 802.11 family of standards known as Wi-Fi®, IEEE 802.15.4 family of standards, peer-to-peer (P2P) networks, among others. In an example, the network interface device 920 may include one or more physical jacks (e.g., Ethernet, coaxial, or phone jacks) or one or more antennas to connect to the communications network 926. In an example, the network interface device 920 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 900, and includes digital or analog communications signals or other intangible medium to facilitate communication of such software. A transmission medium is a machine-readable medium.

The following, non-limiting examples, detail certain aspects of the present subject matter to solve the challenges and provide the benefits discussed herein, among others.

### EXAMPLES

Example 1 is a bridge circuit for use in an automotive battery management system, the bridge circuit comprising: a first communication interface configured to communicate with a control unit using a first bus protocol; a second communication interface configured to communicate with one or more peripheral battery management devices using a second bus protocol; a memory storing a plurality of sequences, an individual sequence of the plurality of sequences comprising one or more commands for the one or more peripheral battery management devices; and a sequence controller coupled to the memory and configured to: retrieve one or more commands associated with a selected sequence from the memory; transmit the retrieved one or more commands to the one or more peripheral battery management devices using the second communication interface; and store data received from the one or more peripheral battery management devices in response to a read command in the memory.

In Example 2, the subject matter of Example 1 optionally includes wherein: the control unit reads the stored data from the memory using the first communication interface.

In Example 3, the subject matter of Example 2 optionally includes wherein: the control unit is configured to read the stored data from the memory asynchronously with respect to the storage of the received data from the one or more peripheral battery management devices.

In Example 4, the subject matter of any one or more of Examples 2-3 optionally include wherein the memory comprises: at least two buffers for respective data types, wherein: the received data is stored in the buffer containing the oldest data; and the control unit reads from the buffer containing the newest data.

In Example 5, the subject matter of any one or more of Examples 2-4 optionally include wherein the memory comprises: at least two buffers for respective data types, wherein: the received data is stored in a ping-pong buffer containing the oldest data; a ping-pong buffer containing the newest data is copied to a read buffer; and the control unit reads from the read buffer.

In Example 6, the subject matter of Example 5 optionally includes wherein: the read buffer is configured such that the data from the ping-pong buffer containing the newest data will not be written to the read buffer when the control unit is reading from the read buffer.

In Example 7, the subject matter of any one or more of Examples 1-6 optionally include wherein the sequence controller is configured to: divide time into discrete time slots with a specified slot length; and maintain a sequence ready list indicating which of the sequences are ready for execution in a current time slot.

In Example 8, the subject matter of Example 7 optionally includes wherein each sequence of the plurality of sequences has an associated priority, and wherein the sequence controller is configured to select a sequence having a highest priority from the sequence ready list for execution.

In Example 9, the subject matter of Example 8 optionally includes wherein: each sequence of the plurality of sequences has an associated initial delay parameter and an associated skip parameter; the initial delay parameter specifies a number of time slots following initialization of the sequence controller before the first execution of the associated sequence; and the skip parameter specifies a number of time slots between successive executions of the associated sequence.

In Example 10, the subject matter of any one or more of Examples 8-9 optionally include wherein: the plurality of sequences are loaded into the memory by the control unit using the first communication interface during a configuration phase; and during runtime following the configuration phase, the sequence controller executes the sequences without further intervention from the control unit.

In Example 11, the subject matter of Example 10 optionally includes wherein: during runtime following the configuration phase, the control unit initiates a reconfiguration phase, including loading a plurality of sequences into the memory using the first communication interface.

In Example 12, the subject matter of any one or more of Examples 10-11 optionally include wherein: during runtime following the configuration phase, the control unit loads an emergency sequence into the memory; and the sequence controller is configured to: execute the emergency sequence the next time the sequence ready list is checked.

In Example 13, the subject matter of any one or more of Examples 7-12 optionally include wherein the sequence controller is configured to: enter a low-power mode when no remaining sequences are ready for execution in a current time slot.

In Example 14, the subject matter of any one or more of Examples 1-13 optionally include wherein at least one of the one or more peripheral battery management devices comprises an analog front-end circuit configured to measure at least one of cell voltage or cell current of at least one of a cell or group of cells in a battery pack.

In Example 15, the subject matter of any one or more of Examples 1-14 optionally include wherein the second bus protocol is different from the first bus protocol.

Example 16 is a method for operating a bridge circuit for use in an automotive battery management system, the bridge circuit comprising: a first communication interface configured to communicate with a control unit using a first bus protocol; a second communication interface configured to communicate with one or more peripheral battery management devices using a second bus protocol; a memory storing a plurality of sequences, an individual sequence of the plurality of sequences comprising one or more commands for the one or more peripheral battery management devices; and a sequence controller coupled to the memory, the method comprising: retrieving, using the sequence controller, one or more commands associated with a selected sequence from the memory; transmitting, using the second communication interface, the retrieved one or more commands to the one or more peripheral battery management devices; and storing, using the sequence controller, data received from the one or more peripheral battery management devices in response to a read command in the memory.

In Example 17, the subject matter of Example 16 optionally includes reading, at the control unit, stored data from the memory over the first communication interface.

In Example 18, the subject matter of any one or more of Examples 16-17 optionally include loading, using the control unit, the plurality of sequences into the memory over the first communication interface during a configuration phase; and executing, during runtime following the configuration phase, using the sequence controller, the sequences without further intervention from the control unit.

Example 19 is a bridge circuit for use in an automotive battery management system, the bridge circuit comprising: a first communication interface configured to communicate with a control unit using a first bus protocol; a second communication interface configured to communicate with one or more peripheral battery management devices using a second bus protocol; a memory storing a plurality of sequences, an individual sequence of the plurality of sequences comprising one or more commands for the one or more peripheral battery management devices; and a sequence controller coupled to the memory and configured to: divide time into discrete time slots with a specified slot length; maintain a sequence ready list indicating which of the sequences are ready for execution in a current time slot; select a ready sequence having a highest priority from the sequence ready list; retrieve one or more commands associated with the selected sequence from the memory; and transmit the retrieved one or more commands to the one or more peripheral battery management devices using the second communication interface.

In Example 20, the subject matter of Example 19 optionally includes wherein: the sequence controller is configured to store data received from the one or more peripheral battery management devices in the memory in response to a read command, wherein: the control unit reads the stored data from the memory using the first communication interface.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific examples that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the terms “or” and “and/or” are used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5). Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4).

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like.

Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the examples should be determined with reference to the appended claims, along with the full scope of equivalents to which such claims are entitled.

What is claimed is:

1. A bridge circuit for use in an automotive battery management system, the bridge circuit comprising:
a first communication interface configured to communicate with a control unit using a first bus protocol;
a second communication interface configured to communicate with one or more peripheral battery management devices using a second bus protocol;
a memory storing a plurality of sequences, an individual sequence of the plurality of sequences comprising one or more commands for the one or more peripheral battery management devices; and
a sequence controller coupled to the memory and configured to:
retrieve one or more commands associated with a selected sequence from the memory;
transmit the retrieved one or more commands to the one or more peripheral battery management devices using the second communication interface; and
store data received from the one or more peripheral battery management devices in response to a read command in the memory.

2. The bridge circuit of claim 1, wherein:
the control unit reads the stored data from the memory using the first communication interface.

3. The bridge circuit of claim 2, wherein:
the control unit is configured to read the stored data from the memory asynchronously with respect to the storage of the received data from the one or more peripheral battery management devices.

4. The bridge circuit of claim 2, wherein the memory comprises:
at least two buffers for respective data types, wherein:
the received data is stored in the buffer containing the oldest data; and
the control unit reads from the buffer containing the newest data.

5. The bridge circuit of claim 2, wherein the memory comprises:
at least three buffers for respective data types, wherein:
the received data is stored in a ping-pong buffer containing the oldest data;
a ping-pong buffer containing the newest data is copied to a read buffer; and
the control unit reads from the read buffer.

6. The bridge circuit of claim 5, wherein:
the read buffer is configured such that the data from the ping-pong buffer containing the newest data will not be written to the read buffer when the control unit is reading from the read buffer.

7. The bridge circuit of claim 1, wherein the sequence controller is configured to:
divide time into discrete time slots with a specified slot length; and
maintain a sequence ready list indicating which of the sequences are ready for execution in a current time slot.

8. The bridge circuit of claim 7, wherein each sequence of the plurality of sequences has an associated priority, and wherein the sequence controller is configured to select a sequence having a highest priority from the sequence ready list for execution.

9. The bridge circuit of claim 8, wherein:
each sequence of the plurality of sequences has an associated initial delay parameter and an associated skip parameter;
the initial delay parameter specifies a number of time slots following initialization of the sequence controller before the first execution of the associated sequence; and
the skip parameter specifies a number of time slots between successive executions of the associated sequence.

10. The bridge circuit of claim 8, wherein:
the plurality of sequences are loaded into the memory by the control unit using the first communication interface during a configuration phase; and
during runtime following the configuration phase, the sequence controller executes the sequences without further intervention from the control unit.

11. The bridge circuit of claim 10, wherein:
during runtime following the configuration phase, the control unit initiates a reconfiguration phase, including loading a plurality of sequences into the memory using the first communication interface.

12. The bridge circuit of claim 10, wherein:
during runtime following the configuration phase, the control unit loads an emergency sequence into the memory; and
the sequence controller is configured to:
execute the emergency sequence the next time the sequence ready list is checked.

13. The bridge circuit of claim 7, wherein the sequence controller is configured to:
enter a low-power mode when no remaining sequences are ready for execution in a current time slot.

14. The bridge circuit of claim 1, wherein at least one of the one or more peripheral battery management devices comprises an analog front-end circuit configured to measure at least one of cell voltage or cell current of at least one of a cell or group of cells in a battery pack.

15. The bridge circuit of claim 1, wherein the second bus protocol is different from the first bus protocol.

16. A method for operating a bridge circuit for use in an automotive battery management system, the bridge circuit comprising:
a first communication interface configured to communicate with a control unit using a first bus protocol;
a second communication interface configured to communicate with one or more peripheral battery management devices using a second bus protocol;
a memory storing a plurality of sequences, an individual sequence of the plurality of sequences comprising one or more commands for the one or more peripheral battery management devices; and
a sequence controller coupled to the memory, the method comprising:
retrieving, using the sequence controller, one or more commands associated with a selected sequence from the memory;
transmitting, using the second communication interface, the retrieved one or more commands to the one or more peripheral battery management devices; and
storing, using the sequence controller, data received from the one or more peripheral battery management devices in response to a read command in the memory.

17. The method of claim 16, comprising:
reading, at the control unit, stored data from the memory over the first communication interface.

18. The method of claim 16, comprising:
loading, using the control unit, the plurality of sequences into the memory over the first communication interface during a configuration phase; and
executing, during runtime following the configuration phase, using the sequence controller, the sequences without further intervention from the control unit.

19. A bridge circuit for use in an automotive battery management system, the bridge circuit comprising:
a first communication interface configured to communicate with a control unit using a first bus protocol;
a second communication interface configured to communicate with one or more peripheral battery management devices using a second bus protocol;
a memory storing a plurality of sequences, an individual sequence of the plurality of sequences comprising one or more commands for the one or more peripheral battery management devices; and
a sequence controller coupled to the memory and configured to:
divide time into discrete time slots with a specified slot length;
maintain a sequence ready list indicating which of the sequences are ready for execution in a current time slot;
select a ready sequence having a highest priority from the sequence ready list;
retrieve one or more commands associated with the selected sequence from the memory; and
transmit the retrieved one or more commands to the one or more peripheral battery management devices using the second communication interface.

20. The bridge circuit of claim 19, wherein:
the sequence controller is configured to store data received from the one or more peripheral battery management devices in the memory in response to a read command, wherein:
the control unit reads the stored data from the memory using the first communication interface.
